(19) United States
(12) Patent Application Publication
(10) Pub. No.: US 2026/0120989 A1
(43) Pub. Date: Apr. 30, 2026

(54) APPARATUS AND METHOD FOR IMPROVED ELECTRON BEAM INSPECTION WITH A CHARGE TREATMENT ELECTRON SOURCE

(71) Applicant: Taiwan Semiconductor Manufacturing Company, Ltd., Hsinchu (TW)

(72) Inventors: Yu-hung KUO, Hsinchu (TW); Wei-Yu CHEN, Hsinchu (TW); Kuang-Shing CHEN, Hsinchu (TW); Xiaomeng CHEN, Hsinchu (TW)

(73) Assignee: Taiwan Semiconductor Manufacturing Company, Ltd., Hsinchu (TW)

(21) Appl. No.: 19/075,686

(22) Filed: Mar. 10, 2025

Related U.S. Application Data
(60) Provisional application No. 63/711,492, filed on Oct. 24, 2024.

(51) Int. Cl. H01J 37/063; H01J 37/256

(52) U.S. Cl. CPC H01J 37/063; H01J 37/256; H01J 2237/06375

(57) ABSTRACT

A detection system includes a first electron source configured to generate a first electron beam and to cause the first electron beam to impinge on a sample, a second electron source configured to generate a second electron beam and to cause the second electron beam to impinge on the sample, a detector, and a control system. The control system is configured to control the first electron source to cause the first electron beam to scan an area of the sample, control a charge state of the sample by varying at least one of a landing energy and a beam current of the second electron beam, control the detector to detect electrons emitted by the sample, receive a detector signal from the detector, and generate a voltage contrast image from the detector signal.

### CROSS-REFERENCE TO RELATED APPLICATION

This application claims priority to U.S. Provisional Patent Application No. 63/711,492, filed on Oct. 24, 2024, the entire disclosure of which is incorporated herein by reference.

### BACKGROUND

Extreme ultraviolet (EUV) lithography is an innovative technology used in semiconductor manufacturing to produce integrated circuits having extremely small and complex patterns. By employing a wavelength of approximately 13.5 nm, EUV lithography enables the creation of features at the nanometer scale, which is desirable for advancing the continued size reduction of semiconductor devices. As the patterns become increasingly intricate, the need for high-resolution inspection systems to accurately detect and address defects becomes more pronounced.

Electron-beam inspection systems, when utilized in conjunction with EUV lithography, offer a promising approach for high-resolution inspection and defect detection. These systems provide the capability for analyzing intricate patterns characteristic of EUV lithography, enabling rapid and precise identification of nanometer-scale defects. Such systems thus facilitate improved yield and performance in semiconductor devices fabricated using EUV technology. Such electron-beam inspection systems can also be configured to operate as stand-alone units at various stages along a semiconductor fabrication processing line and may provide useful information to improve other phases of a semiconductor processing system.

### BRIEF DESCRIPTION OF THE DRAWINGS

The present disclosure is best understood from the following detailed description when read with reference to the accompanying figures. It is emphasized that, following the standard practice in the industry, various features are not drawn to scale and are used for illustration purposes only. In this regard, the dimensions of the various features may be arbitrarily increased or reduced for clarity of discussion.

FIG. 1 is a vertical cross-sectional view of an EUV lithography system, according to various embodiments.

FIG. 2 is a three-dimensional perspective view of an electron beam inspection system, according to various embodiments.

FIG. 3 is a vertical cross-sectional view of an electron beam inspection system, according to various embodiments.

FIG. 4A is a vertical cross-sectional view of the electron beam inspection system of FIG. 3 in which the first electron beam is switched on and the second electron beam is switched off, according to various embodiments.

FIG. 4B is a vertical cross-sectional view of the electron beam inspection system of FIG. 3 in which the first electron beam is switched off and the second electron beam is switched on, according to various embodiments.

FIG. 4C is a first graph illustrating a first time sequence corresponding to the first electron beam that is generated as a sequence of first pulses, according to various embodiments.

FIG. 4D is a second graph illustrating a second time sequence corresponding to the second electron beam that is generated as a sequence of second pulses, according to various embodiments.

FIG. 5A illustrates a frame of pixels in a raster pattern for scanning the first electron beam across a sample, according to various embodiments.

FIG. 5B is a graph illustrating alternating first pulses and second pulses according to a method of scanning a sample with the electron beam inspection system of FIG. 3, according to various embodiments.

FIG. 5C is a graph illustrating alternating first pulses and second pulses according to a method of scanning a sample with the electron beam inspection system of FIG. 3, according to various embodiments.

FIG. 5D is a graph illustrating alternating first pulses and second pulses according to a method of scanning a sample with the electron beam inspection system of FIG. 3, according to various embodiments.

FIG. 5E illustrates a first pixel and a second pixel scanned by the electron beam inspection system of FIG. 3 according to the first graph of FIG. 5B, according to various embodiments.

FIG. 5F illustrates a first line and a second line scanned by the electron beam inspection system of FIG. 3 according to the second graph of FIG. 5C, according to various embodiments.

FIG. 5G illustrates a first frame and a second frame scanned by the electron beam inspection system of FIG. 3 according to the graph of FIG. 5D, according to various embodiments.

FIG. 6 is a vertical cross-sectional view of an electron-beam inspection system 600, according to various embodiments.

FIG. 7 is a flowchart illustrating operations of a method of performing an electron beam inspection of a semiconductor substrate, according to various embodiments.

FIG. 8A illustrates a computer controller for performing the method of FIG. 7, according to various embodiments.

FIG. 8B is a schematic layout of components of the computer controller of FIG. 8A, according to various embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B and C” means “A, B and/or C” (A, B, C, A and B, A and C, B and C, or A, B and C), and does not mean one element from A, one element from B and one element from C, unless otherwise described.

Disclosed embodiments are advantageous by providing a second electron source in an electron beam inspection system that generates voltage contrast images. Voltage contrast imaging of electrically floating structures presents at least two challenges. First, the lack of an electron source results in unstable charging on the wafer surface, leading to high nuisance voltage contrast signals. Second, the absence of a grounding path causes severe charging issues due to insufficient neutralizing electrons from the substrate, which can result in image blur, defocus, or electron beam drift during electron beam scanning. These issues—unstable charging and severe charging—can occur independently or simultaneously. Disclosed embodiments address such charging-related challenges related to voltage contrast imaging of electrically isolated structures by providing a second electron source in addition to the primary electron source used for imaging. The second electron source provides a second electron beam of charge-neutralizing electrons that control the charge state of the floating structure to be positive, neutral, or negative by varying a landing energy landing energy and/or an intensity of the second electron beam thus mitigating charging issues and improving the quality of voltage contrast images.

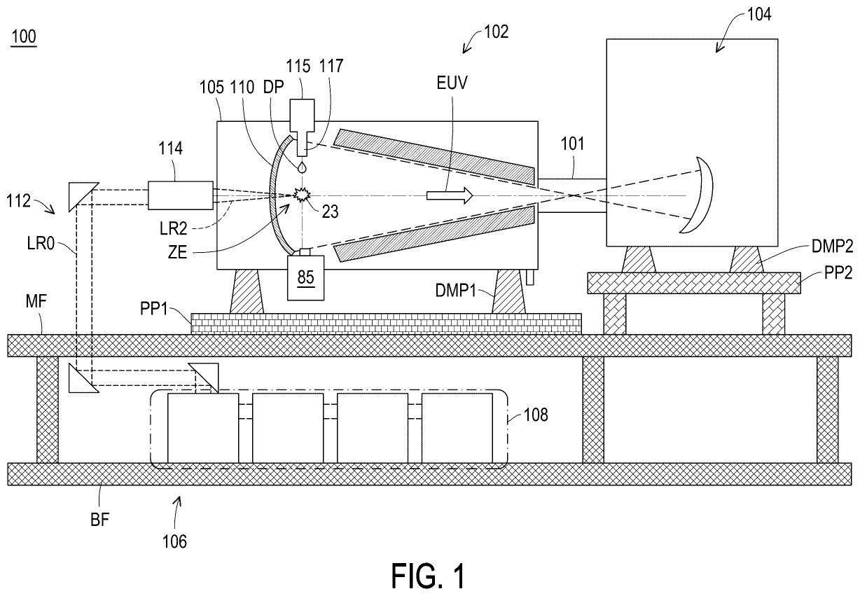

FIG. 1 is a vertical cross-sectional view of an extreme ultraviolet (EUV) lithography system 100 with an EUV radiation source 102, according to various embodiments. The EUV lithography system 100 further includes an exposure device 104, such as a scanner, and an excitation laser source 106. As shown in FIG. 1, in some embodiments, the EUV radiation source 102 and the exposure device 104 are installed on a main floor MF of a clean room, while the excitation laser source 106 is installed in a base floor BF located under the main floor. Each of the EUV radiation source 102 and the exposure device 104 are placed over pedestal plates PP1 and PP2 via dampers DMP1 and DMP2, respectively. The EUV radiation source 102 and the exposure device 104 are coupled to one another by a coupling mechanism, which includes a focusing unit 101.

The EUV lithography system 100 is designed to expose a resist layer, formed over a substrate, to EUV radiation. The resist layer is a material sensitive to the EUV radiation. The EUV lithography system 100 employs the EUV radiation source 102 to generate EUV radiation, such as EUV radiation having a wavelength ranging between about 1 nm and about 50 nm. In an embodiment, the EUV radiation source 102 generates EUV radiation with a peak wavelength that is approximately 13.5 nm. In this embodiment, the EUV radiation source 102 utilizes a mechanism of laser-produced plasma to generate the EUV radiation.

The exposure device 104 includes various reflective optical components, such as convex mirrors, concave mirrors, and flat mirrors (not shown). The exposure device 104 further includes a mask-holding mechanism including a mask stage, and a wafer-holding mechanism (e.g., a substrate-holding mechanism). The EUV radiation generated by the EUV radiation source 102 is guided by the reflective optical components onto a mask secured on the mask stage (both not shown in FIG. 1). Because gas molecules absorb EUV radiation, the EUV lithography system 100 is maintained in a vacuum or a low-pressure environment to avoid EUV intensity loss.

In some embodiments, a reticle is introduced into the exposure device 104, which operates under vacuum conditions. The reticle is positioned above a substrate coated with a photoresist layer, and a pellicle is mounted on the reticle. The exposure device 104 includes a projection optics module that images the pattern of the mask onto a semiconductor substrate, which has a resist coated thereon and which is secured on a substrate stage of the exposure device 104. The projection optics module generally includes reflective optics. The EUV radiation directed from the mask, carrying the image of the pattern defined on the mask, is collected by the projection optics module, thereby forming an image on the resist.

In various embodiments, the semiconductor substrate is a semiconductor wafer, such as a silicon wafer or other type of wafer to be patterned. The semiconductor substrate is coated with a resist layer that is sensitive to the EUV radiation. Various components, including those described above, are integrated and are operable to perform lithography exposure processes. The EUV lithography system 100 may further include other modules or be integrated with (or be coupled with) other modules.

As shown in FIG. 1, the EUV radiation source 102 includes a droplet generator 115 and a laser-produced plasma collector mirror 110, enclosed by a chamber 105. The droplet generator 115 generates a plurality of target droplets DP, which are supplied into the chamber 105 through a nozzle 117. In some embodiments, the target droplets DP are Sn, Li, or an alloy of Sn and Li. In some embodiments, the target droplets DP each have a diameter in a range from about 10 microns to about 100 microns. For example, in an embodiment, the target droplets DP are Sn droplets, each having a diameter of about 10 microns, about 25 microns, about 50 microns, or any diameter between these values.

The excitation laser beam LR2 generated by the excitation laser source 106 is a pulsed beam. The laser pulses of laser beam LR2 are generated by the excitation laser source 106. The excitation laser source 106 includes a laser generator 108, laser guide optics 112, and a focusing apparatus 114. In some embodiments, the laser generator 108 includes a carbon dioxide (CO₂) or a neodymium-doped yttrium aluminum garnet (Nd:YAG) laser source with a wavelength in the infrared region of the electromagnetic spectrum. For example, the laser source 108 has a wavelength of 9.4 microns or 10.6 microns in an embodiment. The laser beam LR0 generated by the excitation laser source 106 is guided by the laser guide optics 112 and focused, by the focusing apparatus 114, into the excitation laser beam LR2 that is introduced into the EUV radiation source 102. Other than CO₂ and Nd:YAG lasers, in some embodiments, the laser beam LR2 is generated by a gas laser including an excimer gas discharge laser, helium-neon laser, nitrogen laser, transversely excited atmospheric (TEA) laser, argon ion laser, copper vapor laser, KrF laser or ArF laser; or a solid state laser including Nd: glass laser, ytterbium-doped glasses or ceramics laser, or a ruby laser.

The laser beam LR2 is directed through windows or lenses (not shown) into the zone of excitation ZE. The windows or lenses may be made of a suitable material that is substantially transparent to the laser beams. The generation of the laser pulses is synchronized with the ejection of the target droplets DP through the nozzle 117. As the target droplets move through the excitation zone, the pre-pulses heat the target droplets and transform them into low-density target plumes. A delay between the pre-pulse and the main pulse is controlled to allow the target plume to form and expand to an optimal size and geometry. In various embodiments, the pre-pulse and the main pulse have the same pulse duration and peak power. When the main pulse heats the target plume, a high-temperature plasma is generated. The plasma emits EUV radiation, which is collected by the collector mirror 110. The collector mirror 110, which is configured as an EUV collector mirror, further reflects, and focuses the EUV radiation which is provided to the exposure device 104. A target droplet DP that does not interact with the laser pulses is captured by the droplet catcher 85.

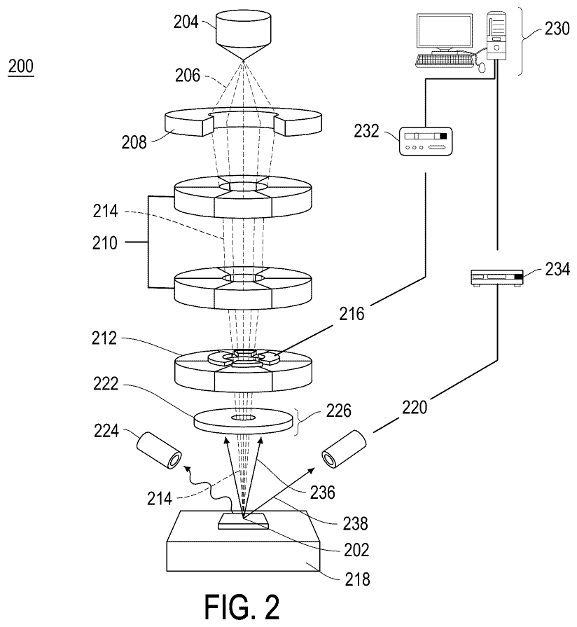

FIG. 2 is a three-dimensional perspective view of an electron-beam inspection system 200, according to various embodiments. The electron-beam inspection system 200 includes a plurality of components designed to generate, focus, and detect electron beams (206, 214) for high-resolution imaging of a sample 202. The electron-beam inspection system 200, includes an electron source 204 that generates a primary electron beam 206, an anode 208, condenser lenses 210, an objective lens 212, scanning coils 216, a motorized stage 218, a secondary electron detector 220, a backscattering detector 222, and an x-ray detector 224. Each of these components is described in detail below.

The primary electron beam 206, generated by the electron source 204, is accelerated toward the sample 202 by the anode 208, imparting the necessary energy for interaction with the sample 202 surface. Condenser lenses 210, positioned between the electron source 204 and the objective lens 212, focus the primary electron beam 206 to generate a focused electron beam 214 and control its intensity and diameter. The objective lens 212, including scanning coils 216, enables precise positioning and scanning of the focused electron beam 214 over a surface of the sample 202. The motorized stage 218 holds the sample 202 securely and allows for precise movement during the scanning process.

As the focused electron beam 214 interacts with the sample 202, different types of signals are produced, which are detected by the various detectors (220, 222, 224). The secondary electron detector 220 captures low-energy secondary electrons 238, providing high-resolution images with surface detail. In contrast, the backscattering detector 222 collects backscattered electrons, offering contrast based on compositional differences (i.e., differences in atomic number of materials) within the sample 202. Additionally, an x-ray detector 224 measures characteristic x-rays emitted by the sample 202, facilitating elemental analysis. Together, these components enable the electron-beam inspection system 200 to produce detailed images and provide compositional information about the sample 202.

In some embodiments, the electron-beam inspection system 200 is coupled with the EUV lithography system 100, but in other embodiments, the electron-beam inspection system 200 operates as a stand-alone unit at various stages along a semiconductor fabrication processing line. When coupled with the EUV lithography system 100, different approaches are used depending on the specific design and requirements of the semiconductor device manufacturing line, according to various embodiments. For example, in some embodiments, the electron-beam inspection system 200 is not installed in the same vacuum chamber as the EUV patterning module but rather in a separate inspection module. However, in such embodiments, the process is configured to ensure efficient wafer transfer between the EUV lithography tool 100 and the electron-beam inspection system 200, either maintaining vacuum or allowing for controlled venting.

According to various embodiments, the wafer (e.g., the sample 202) is transferred from the EUV exposure device 104 to the electron-beam inspection system 200 without breaking vacuum. This configuration is advantageous because it minimizes the risk of contamination, which is particularly important in EUV lithography, where even small particles can significantly impact yield due to the fine feature sizes being patterned. A vacuum-based wafer handling system serves to avoid introducing contaminants during the transfer process. This can be achieved by integrating vacuum-compatible robotic handling systems (not shown) that shuttle wafers between the EUV lithography tool 100 and the electron-beam inspection system 200 through vacuum-tight load locks.

Alternatively, in some embodiments, the wafer is transferred to the electron-beam inspection system 200 with a controlled venting process, where the vacuum is broken temporarily but under highly controlled conditions to prevent contamination. In such cases, the chambers are purged with clean gases, and the time spent outside of vacuum is minimized to reduce the possibility of particulate or chemical contamination. The decision on whether to maintain vacuum or allow for controlled venting during wafer transfer depends on the specific design goals of the semiconductor device fabrication line, the criticality of contamination control, and throughput considerations. Maintaining vacuum throughout the process may be implemented in high-end manufacturing environments, as it enhances cleanliness and reduces the potential for yield loss due to defects introduced during handling. However, both configurations can be successfully implemented, with the electron-beam inspection system 200 integrated as an important tool for defect detection in the EUV lithography process. Alternatively, as described above, the electron-beam inspection system 200 is configured as a stand-alone module at various stages along a semiconductor device fabrication processing line, independently of the EUV lithography system 200, in other embodiments.

According to an embodiment, the electron source 204 generates a primary electron beam 206 that serves as the initiating beam for the inspection process. The electron source 204, in this embodiment, is a thermionic or field-emission gun, depending on the required beam properties. The primary electron beam 206 generated by the electron source 204 is accelerated toward the sample 202 by an anode 208, positioned downstream of the electron source 204. The anode 208 applies a potential difference to the primary electron beam 206 relative to the electron source 204, resulting in an electric field that imparts the necessary energy to the focused electron beam 214 to promote interactions with the sample's surface.

Following the anode 208, the focused electron beam 214 passes through a series of condenser lenses 210, which focus the focused electron beam 214 and control its intensity and diameter. The condenser lenses 210 are arranged to produce a precise and narrow electron beam 214 that remains well-focused as it approaches the sample 202. This focused electron beam 214 enables high-resolution imaging of the sample surface and enhances the beam's interaction efficiency.

Downstream from the condenser lenses 210, according to an embodiment, the objective lens 212, which includes scanning coils 216, directs the focused electron beam 214 onto the sample 202 and enables scanning of the beam over the sample's 202 surface. The objective lens 212 further refines the focus of the focused electron beam 214 to a precise spot on the sample 202, facilitating high-resolution imaging. The scanning coils 216, integrated within the objective lens 212, allow for precise, controlled scanning by deflecting the focused electron beam 214 in a raster pattern, enabling comprehensive surface inspection and mapping.

According to an embodiment, the backscattering detector 222 includes a detector body 226 having an annular shape and includes electron detectors (not shown) configured to detect backscattered electrons 236. The annular configuration of the backscattering detector 222 surrounds the optical axis of the focused electron beam 214, allowing it to capture electrons 236 backscattered from the sample 202 surface across a broad angular range. The annular configuration provides optimal coverage for detecting electrons 236 that scatter at high angles relative to the incident beam 214, enhancing the detector's ability to capture signal variations based on the atomic number and composition of the sample 202.

The electron detectors within the annular backscattering detector 222 are strategically arranged to efficiently detect the backscattered electrons. These electron detectors generate an electrical signal in response to the energy transferred from incoming electrons. By arranging multiple semiconductor elements around the detector's annular perimeter, the backscattering detector 222 can achieve both high sensitivity and spatial resolution, which are advantageous for producing contrast in images based on variations in composition across the sample surface 202.

The annular shape and semiconductor-based detection capability of the backscattering detector 222 allow it to provide detailed compositional information, facilitating material characterization and analysis of structural features within the sample 202. This configuration further enables the electron-beam inspection system 200 to produce enhanced images with compositional contrast, supporting more precise inspection and analysis.

According to certain embodiments, the electron detectors suitable for detecting backscattered electrons in the backscattering detector 222 include silicon-based photodiodes, avalanche photodiodes (APDs), and PIN diodes. These electron detectors are advantageous for electron detection due to their high sensitivity, fast response times, and capability to operate under low-noise conditions, which are beneficial for detecting subtle variations in backscattered electron intensity.

In one embodiment, a silicon-based photodiode is provided as a detector, where the interaction of backscattered electrons with the semiconductor material generates electron-hole pairs. This interaction produces an electrical signal that is proportional to the electron energy absorbed, enabling the photodiode to effectively capture backscattered electrons with minimal signal degradation.

In another embodiment, avalanche photodiodes (APDs) are provided as suitable electron detectors. APDs are designed to operate with internal gain through an avalanche multiplication process, where a single high-energy electron interaction can initiate a cascade of electron-hole pairs, amplifying the signal. Avalanche amplification is advantageous for detecting low-intensity backscattered electrons because the amplification increases the detector's sensitivity and enhances the accuracy of material contrast in imaging.

Additionally, in a further embodiment, PIN diodes, structured with p-type, intrinsic, and n-type layers, are provided for backscattered electron detection. The intrinsic region provides a wider depletion region, increasing the electron absorption efficiency and thus enhancing sensitivity to backscattered electrons. The design of PIN diodes allows for improved charge collection efficiency, making them suitable for detecting both high and low-energy backscattered electrons with high precision. The above-described electron detectors, whether silicon-based photodiodes, avalanche photodiodes, or PIN diodes, contribute to the capability of the backscattering detector 222 to accurately detect backscattered electrons and provide compositional contrast information in the electron-beam inspection system 200.

Secondary electrons 238 are ejected when primary electrons (i.e., from the focused electron beam 214) interact with the surface of a sample, and these electrons are valuable for imaging the topography of the surface due to their sensitivity to surface details. One type of secondary electron detector 220 is the Everhart-Thornley detector, which includes a metal collector electrode positioned near the sample. This electrode is positively biased, attracting secondary electrons 238 to a scintillator material, which emits light when struck by the electrons. The light is then detected by a photomultiplier tube, and the resulting signal is used to form an image. This detector provides high-resolution and high-contrast imaging, making it ideal for observing fine surface details, though it requires careful placement to avoid shadowing.

Another type of secondary electron detector 220 is the annular detector, which uses a ring-shaped array of electrodes (not shown) surrounding the sample area. This configuration can be used to collect secondary electrons 238 from a broader region, offering high-throughput imaging applications, though it may not match the resolution and contrast of the Everhart-Thornley detector. In-lens detectors are also employed in some embodiments, positioned inside the microscope column near the lens system. These detectors collect secondary electrons 238 directly from the sample surface before they scatter too far, leading to better signal-to-noise ratios and improved resolution, particularly for observing surface morphology. However, the design of in-lens detectors may limit their ability to detect secondary electrons 238 from deeper regions of the sample.

Secondary electron detection allows for imaging surface topography, which is useful for inspecting microstructures in semiconductor devices like transistors and interconnects. The high-resolution imaging provided by secondary electron detectors 220 allows for the detection of defects, surface roughness, etching processes, and contamination at the nanometer scale, which directly impacts the quality and yield of semiconductor components. An electron-beam inspection system 200 equipped with secondary electron detectors 220 can create 3D surface reconstructions, which are useful for analyzing etch depth and feature alignment. Secondary electron detectors 220 are also useful in failure analysis by identifying issues such as cracks, voids, and poor thin-film adhesion, which can negatively affect device performance. Secondary electron detection is particularly valuable in generating high-contrast images, but care must be taken to avoid charging effects, especially when imaging insulating materials, as described in greater detail, below.

According to an embodiment, the electron-beam inspection system 200 further includes a computer controller 230, a scan generator 232, and a signal amplifier 234. These components are configured to control the operation of the inspection tool 200, manage scanning patterns, and process detected signals to generate high-resolution images with compositional information. Each component is described in detail below.

According to an embodiment, the computer controller 230 is configured to coordinate and manage the overall operation of the electron-beam inspection system 200. The computer controller 230 includes a processor and associated memory for executing instructions related to beam control, scanning parameters, image processing, and data analysis. The computer controller 230 communicates with various subsystems, including the electron source 204, detectors (220, 222, 224), scan generator 232, and signal amplifier 234, to provide precise control over the beam's path, scanning resolution, and data acquisition timing. Additionally, the computer controller 230 processes the output from the detectors and can apply image-processing algorithms to enhance detail and contrast in the resulting images.

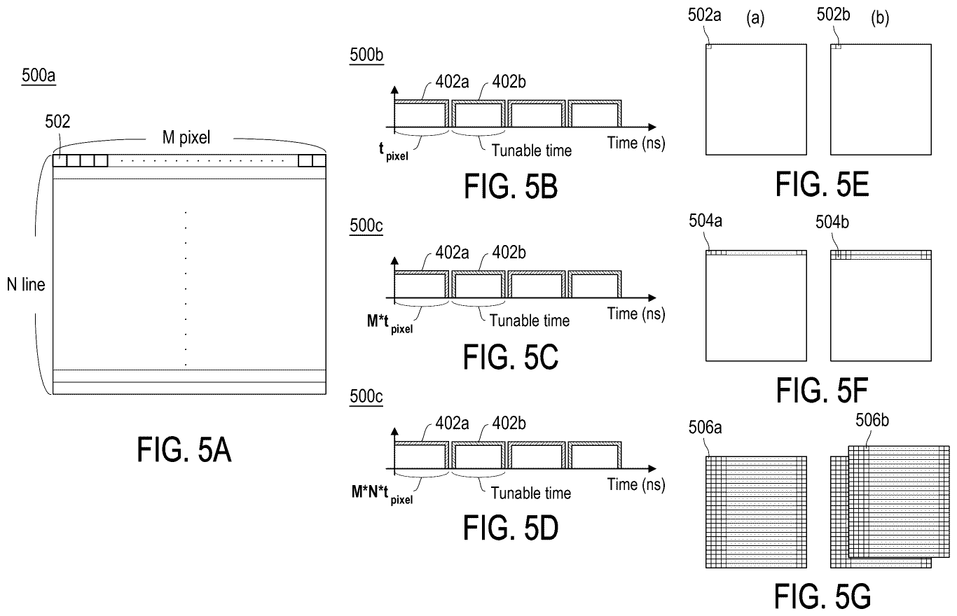

According to another embodiment, the scan generator 232 includes scanning patterns that direct the focused electron beam 214 over the sample surface 202 in a raster pattern (e.g., see FIG. 5A) or other predetermined pattern. The scan generator 232 provides control signals to the scanning coils 216 within the objective lens 212, precisely adjusting the beam's position to achieve the desired scan coverage and resolution. The scan generator 232 thus enables detailed surface inspection and guidance of interaction between the focused electron beam 214 and the sample 202, facilitating accurate data acquisition and image generation.

In addition, according to a further embodiment, a signal amplifier 234 is provided to amplify signals received from the detectors, including the secondary electron detector 220, backscattering detector 222, and x-ray detector 224. The signal amplifier 234 processes these detected signals by increasing their amplitude, which is advantageous for enhancing the signal-to-noise ratio. This amplification step can sufficiently amplify low-intensity signals, which may represent fine structural or compositional details, for accurate processing and imaging. The signal amplifier 234 interfaces directly with the detectors and transmits the amplified signals to the computer controller 230 for further analysis.

Together, the computer controller 230, scan generator 232, and signal amplifier 234 enable the electron-beam inspection system 200 to achieve precise control, detailed scanning, and high-resolution image formation, enhancing the tool's inspection and analytical capabilities. According to an embodiment, the electron-beam inspection system 200 is configured to generate voltage contrast images, which allow the determination of the presence of defects in a semiconductor substrate 202 or semiconductor device 202. This capability is particularly advantageous for assessing the quality and reliability of semiconductor device materials and components.

Voltage contrast imaging is a valuable technique that enables the visualization and analysis of the electrical properties of micro- and nano-scale structures on integrated circuits (ICs). This method relies on the interaction between the electron beam 214 and the sample 202 surface, where local electric fields influence secondary electrons 238. The resulting variations in electrical potential across the sample are visualized as differences in brightness or contrast in the SEM image, allowing electrically active or inactive regions to be distinguished. This makes the technique useful for detecting defects such as open circuits, short circuits, and improper doping and for locating failure points in ICs by identifying unexpected electrical characteristics. Additionally, voltage contrast imaging plays a role in process monitoring during semiconductor device fabrication by verifying the functionality of patterned structures, including metal interconnects and transistors, and distinguishing between insulating and conductive materials.

When utilizing the electron-beam inspection system 200 to generate voltage contrast images, the focused electron beam 214 interacts with the sample 202 (i.e., semiconductor substrate or device), and as the focused electron beam 214 scans the surface, the beam induces local changes in the electrical potential of the sample 202, particularly in regions where defects or inhomogeneities are present. These changes in voltage can occur due to variations in the material's doping concentration, surface charge distributions, or structural discontinuities.

The backscattering detector 222 and secondary electron detector 220 capture the backscattered electrons 236 and secondary electrons 238 that provide information about the voltage contrast across the sample 202. According to an embodiment, the computer controller 230 processes the detected signals, and applies algorithms to analyze the variations in detected electron intensity corresponding to the localized voltage differences. The resulting images highlight areas of interest, such as defects, impurities, or structural anomalies, within the sample 202.

In addition, the scan generator 232 directs the focused electron beam 214 in a controlled manner over the surface of the sample 202, enabling detailed mapping of the voltage contrast. This scanning capability allows for high-resolution imaging, making it possible to identify even subtle defects that could affect the performance and reliability of the semiconductor device 202. Overall, the ability of the electron-beam inspection system 200 to generate voltage contrast images serves as a powerful diagnostic technique for semiconductor device manufacturing and quality control, facilitating the identification of defects and contributing to the development of high-performance semiconductor materials and devices.

In voltage contrast imaging, the brightness variations in the resulting image are influenced by the effects of positively and negatively charged regions on the trajectories and energies of emitted secondary electrons 238. Positively charged areas on the sample surface create electric fields that attract the negatively charged secondary electrons 238, reducing the number of electrons escaping toward the secondary electron detector 220. This results in a lower signal intensity, causing positively charged regions to appear darker in the image. Conversely, negatively charged areas generate electric fields that repel secondary electrons 238, enhancing their escape toward the secondary electron detector 220 and increasing the signal intensity. As a result, negatively charged regions appear brighter in the voltage contrast image. The extent of these brightness variations depends on factors such as the magnitude of the surface charge, the electron beam energy, and the detector's efficiency in collecting secondary electrons 238. These contrast differences provide valuable insights into the sample's electrical properties, enabling the identification and analysis of specific features for semiconductor device inspection and failure analysis.

As mentioned above, voltage contrast imaging of electrically floating structures presents at least two challenges. First, the lack of an electron source results in unstable charging on the wafer surface, leading to high nuisance voltage contrast signals. Second, the absence of a grounding path causes severe charging issues due to insufficient neutralizing electrons from the substrate, which can result in image blur, defocus, or electron beam drift during electron beam scanning. These issues—unstable charging and severe charging—can occur independently or simultaneously.

In this regard, an electrically floating structure can become positively charged when the rate of secondary and backscattered electron emission exceeds the current of the incoming focused electron beam 214. This occurs because the emitted electrons, which consist of negatively charged secondary electrons 238 (low-energy electrons generated by the interaction of the electron beam with the sample) and backscattered electrons 236 (higher-energy primary electrons reflected from the sample), leave the structure at a higher rate than the incoming electrons can replenish, leaving a net positive charge on the sample 202.

In a floating structure, there is no direct electrical connection to ground or a conductive pathway to neutralize the imbalance. As a result, the loss of electrons can create a net positive charge on the structure that generates an electric field. The resulting electric field influences the trajectories of both the incoming electron beam and the emitted electrons, potentially leading to image distortions, reduced resolution, or artifacts in voltage contrast imaging. Disclosed embodiments address such charging-related challenges related to electrically isolated structures as follows.

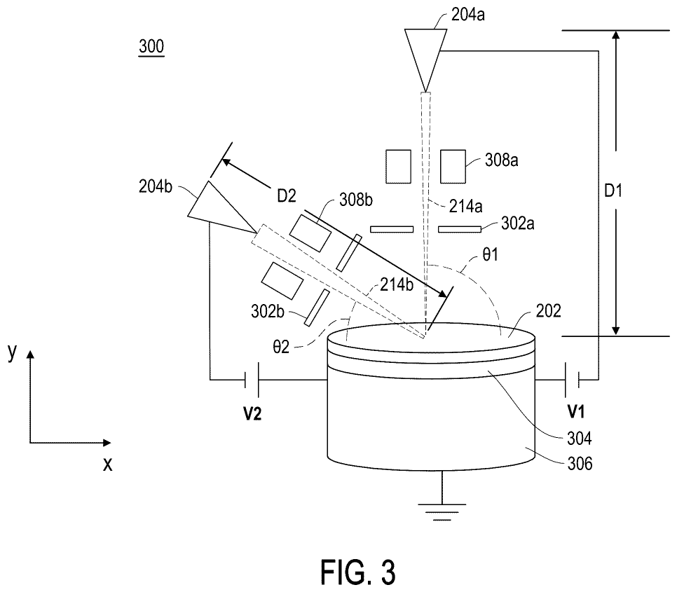

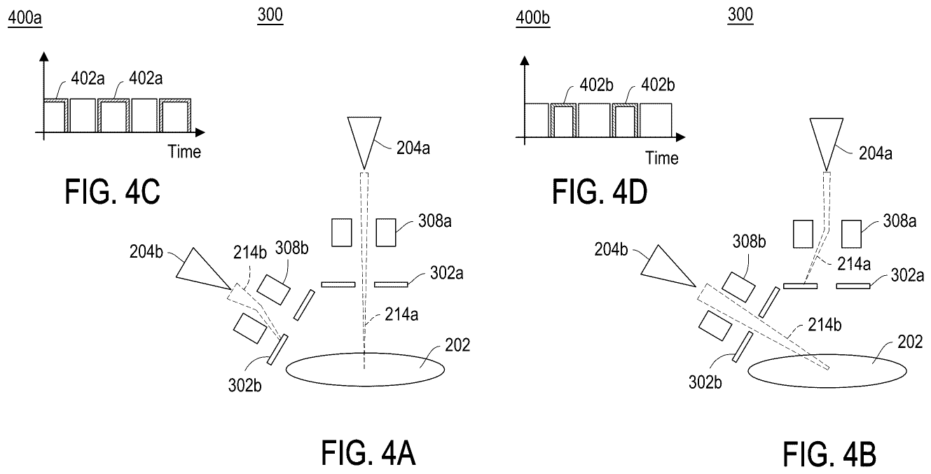

FIG. 3 is a vertical cross-sectional view of an electron beam inspection system 300, according to various embodiments. The electron beam inspection system 300 includes a first electron source 204a configured to generate a first electron beam 214a and to cause the first electron beam to impinge on the sample 202 at a first angle θ1 and a second electron source 204b configured to generate a second electron beam 214b and to cause the second electron beam 214b to impinge on the sample 202 at a second angle θ2 that is different from the first angle θ1. The second electron source 204b is configured to generate the second electron beam 214b to be obliquely incident, as shown, and to generate the second electron beam 214b as a defocused electron beam that covers an area that is larger than an area scanned by the first electron beam 214a. As such, the second electron source 204b can be referred to as a “flood gun” that floods a certain area with electrons to control an overall charge state of the area. As shown in FIG. 3, the electron beam inspection system 300 further includes first blankers 302a and second blankers 302b, which are used to switch the first electron beam 214a and the second electron beam 214b on and off, as described in greater detail with reference to FIGS. 4A and 4C, below

As further shown in FIG. 3, in an embodiment, the sample 202 being inspected is a silicon layer top portion of a silicon-on-insulator (SOI) wafer in which a buried oxide layer 304 separates the silicon layer top portion 202 from the lower portion of a silicon wafer 306. As such, the silicon layer top portion 202 is electrically floating and subject to charging issues as described above. In some embodiments, the lower portion of the silicon wafer 306 is doped and electrically grounded. In some embodiments, the first electron source 204a and the second electron source 204b are held at different electrostatic potentials (i.e., voltages V1 and V2) relative to the lower portion of the silicon wafer 306. These voltages generate electric fields that impart specific landing energies (LE1, LE2) to the first electron beam 214a and the second electron beam 214b. The first electron source 204a and the second electron source 204b are shown in FIG. 3 as electrically connected to the 306 for simplicity of illustration but need not be physically connected to the lower portion of the silicon wafer 306. Alternatively, each of the first electron source 204a, the second electron source 204b, and the silicon wafer are connected to a common ground connection (not shown) in other embodiments.

A first landing energy LE1 of the first electron beam 214a is tuned to a value that is appropriate for generating voltage contrast images. For example, LE1 is between about 0.1 keV and about 50 keV in various embodiments. In some embodiments, the second landing energy LE2 is different from LE1 and is varied as needed to control a charge state of the sample 202. According to various embodiments, LE2 is between about 0.1 keV and about 5 keV. The first electron source 204a is located at a first distance D1 from the sample 202 along a first direction (i.e., along the y-axis) that is approximately perpendicular to a surface of the sample 202 such that the first angle θ1 is approximately 90° relative to the surface of the sample 202. As further shown in FIG. 3, the second electron source 204b is located at a second distance D2 from the sample 202 along a second direction that subtends an oblique angle relative to the first direction such that the second angle θ2 is between about 0° and about 90° relative to the surface of the sample 202. In other embodiments the second angle θ2 is between about 10° and about 80°, between about 20° and about 70°, between about 30° and about 60°, between about 40° and about 50°, or θ₂ is approximately 45° in other embodiments. According to various embodiments, the second electron source 204b is re-configurable such that the second angle θ₂ is adjustable and configured to be set to a user-determined angle. Alternatively, in other embodiments, the second electron source 204b is configured to be held at a fixed value of the second angle θ₂.

Although not explicitly shown in FIG. 3, the sample is attached to a stage 218 (e.g., see FIG. 2) that is configured to position the sample 202 relative to the first electron source 204a and the second electron source 204b. To generate the required electric fields, the first electron source 204a is maintained at a first voltage V1 relative to a voltage (e.g., ground; V=0) of the stage 218, and the second electron source 204b is maintained at a second voltage V2 relative to the voltage of the stage. In some embodiments, the first voltage V1 is different from the second voltage V2. A first electric field E1 generated by the first electron source 204a is given by E1=V1/D1, and a second electric field E2 generated by the second electron source 204b is given by E2=V2/D2. The first landing energy LE1 of electrons in the first electron beam 214a is given by LE1=q V1, and the second landing energy LE2 of electrons in the second electron beam 214b is given by LE2=q V2, where q=1.602×10⁻¹⁹ Coulombs is the charge on a single electron.

A first electromagnetic device 308a and a second electromagnetic device 308b (e.g., condenser lens 210, objective lens 212, scanning coils 216) as disclosed herein in reference to FIG. 2, are respectively used to control a trajectory and focus of each of the first electron beam 214a and the second electron beam 214b. For example, according to various embodiments, the first electromagnetic device 308a controls the first electron beam 214a to have a first diameter that is between about 1 nm and about 50 nm at the surface of the sample 202, and the second electromagnetic device 308b controls the second electron beam 214b to have a second diameter that is between about 6 mm and about 8 mm at the surface of the sample 202. Further, an electron intensity in the first electron beam 214a and the second electron beam 214b can be controlled by controlling an electrical current supplied to the first electron source 204a and the second electron source 204b, respectively. According to various embodiments, a first electron current of the first electron beam 214a is between about 5.0×10⁻⁹ A and about 1.5×10⁻⁸ A, and a second electron current of the second electron beam 214b is between about 8.0×10⁻⁵ A and about 1.2×10⁻⁴ A.

FIG. 4A is a vertical cross-sectional view of the electron beam inspection system 300 of FIG. 3 in which the first electron beam 214a is switched on and the second electron beam 214b is switched off, and FIG. 4B is a vertical cross-sectional view of the electron beam inspection system 300 of FIG. 3 in which the first electron beam 214a is switched off and the second electron beam 214b is switched on, according to various embodiments. FIG. 4C is a first graph 400a illustrating a first time sequence corresponding to the first electron beam 214a that is generated as a sequence of first pulses 402a, and FIG. 4D is a second graph 400b illustrating a second time sequence corresponding to the second electron beam 214b that is generated as a sequence of second pulses 402b, according to various embodiments. The on/off switching of the first electron beam 214a and the second electron beam 214b is controlled by the electromagnetic devices (308a, 308b) and the blankers (302a, 302b). In this regard, an electron beam (214a, 214b) is switched off by controlling the electromagnetic devices (308a, 308b) to deflect the electron beam (214a, 214b) such that it hits the blankers (302a, 302b) rather than hitting the sample 202.

In various embodiments, the second electron source 204b (i.e., the flood gun) has a tunable time-pulse period and a wide range of tunable second landing energies LE2 relative to corresponding timings and first landing energies LE1 of the first electron source 204a. The second electron source 204b supplies a flux of additional electrons that modifies the charging state of the sample 202 (e.g., a wafer surface). The second electron source 204b supplies the additional electrons before and/or after the first electron source 204a performs a scanning operation that generates detected electrons (236, 238) that are used to generate an image. The timing and second landing energy LE2 of the second electron source 204b are tuned to achieve a stable and enhanced voltage-contrast defect signal on an electron beam inspection image on fully and partially floating structures.

In this regard, the electrons supplied by the second electron source 204b address the challenges described above by “treating” the sample (i.e., modifying the charge state) with the second electron source 204b before, during, or after generating voltage contrast images using the first electron source 204a.

As described below, electrons are supplied by the second electron source 204b at various second landing energies LE2 and pulse timings relative to corresponding first landing energies LE1 and pulse timings of the first electron source 204a. For example, as shown in 4C, the first electron beam 214a is generated as a sequence of first pulses 402a and the second electron beam 214b is generated as a sequence of second pulses 402b. Further, as can be seen by comparing FIGS. 4C and 4D, each one of the sequence of second pulses 402b has a time offset relative to the sequence of first pulses 402a such that the sequence of first pulses 402a and the sequence of second pulses 402b are alternating. Alternatively, in other embodiments, the first pulses 402a and the sequence of second pulses 402b can be partially or completely overlapping spatially and temporally. Each first pulse 402a corresponds to scanning a certain area of the sample 202 by the first electron beam 214a and each second pulse 402b corresponds to a pulse of electrons provided by the second electron beam 214b covering an area that is at least as large as an area scanned by the first electron beam 214a.

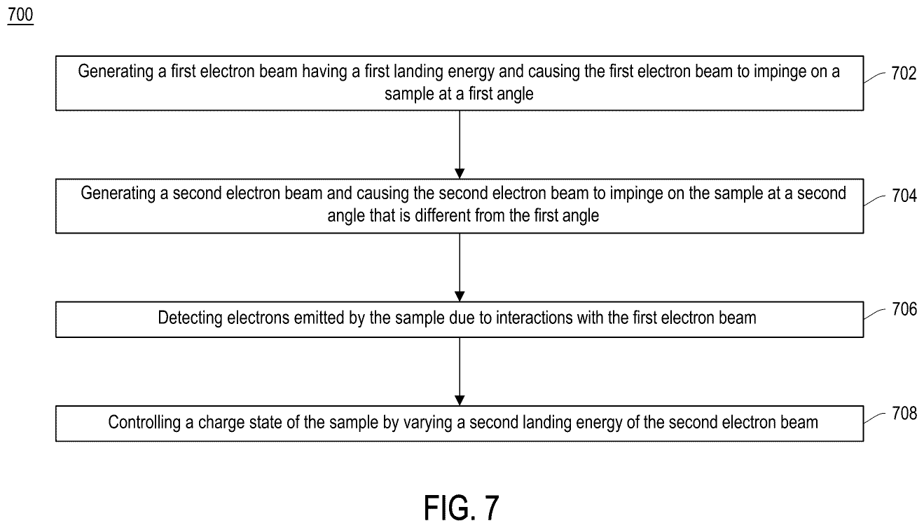

FIG. 5A illustrates a frame 500a of pixels 502 in a raster pattern for scanning the first electron beam 214a across a sample 202, according to various embodiments. The frame 500a is a portion of an image in some embodiments and represents a full image in other embodiments. FIGS. 5B, 5C, and 5D illustrate time-sequence graphs (500b, 500c, 500d) of alternating first pulses 402a and second pulses 402b according to a method (e.g., see FIG. 7) of scanning the sample 202 with the electron beam inspection system 300 of FIG. 3, according to various embodiments. In this regard, the second electron source 204b can be used to treat the sample after the first electron source 204a irradiates (1) a portion of the sample 202 corresponding to a pixel 502 (according to graph 500b of FIG. 5B), (2) a portion of the sample 202 corresponding to a line 504 of pixels 502 (according to graph 500c of FIG. 5C), and/or (3) a portion of the sample corresponding to a frame 506 of pixels 502 (according to graph 500c of FIG. 5C).

In this regard, FIG. 5E illustrates a first pixel 502a and a second pixel 502b scanned by the electron beam inspection system 300 of FIG. 3 according to the first graph 500b of FIG. 5B, FIG. 5F illustrates a first line 504a and a second line 504b scanned by the electron beam inspection system 300 of FIG. 3 according to the second graph 500c of FIG. 5C, and FIG. 5G illustrates a first frame 506a and a second frame 506b scanned by the electron beam inspection system 300 of FIG. 3 according to the third graph 500d of FIG. 5D, according to various embodiments. As illustrated, for example, in FIGS. 5B, 5C, and 5D, the second pulses 402b are provided before or after each first pulse 402a. Further, the second pulse 402b is provided over a first area before or after that first area is irradiated with a first pulse 402a. As described above, the second pulses 402b cover a second area that is greater than equal to a size of the first area.

According to various embodiments, a single pixel corresponds to an area that is between about 1 nm and about 50 nm, and a one-pixel exposure time tₚᵢₓₑₗ required for the first electron source 204a to scan a single pixel is between about 1 ns to about 15 ns. Thus, according to various embodiments, each one of the sequence of first pulses 402a lasts for a first time that is an integer multiple of the one-pixel exposure time tₚᵢₓₑₗ depending on whether each one of the sequence of first pulses scans a single pixel 502, a line 504 of pixels, or a rectangular block 506 (i.e., a frame) of pixels 502. Thus, according to various embodiments, a line 504 of pixels 502 includes an integer number M of pixels 502, and a frame 506 includes an integer number N of lines 504. As such, each first pulse 402a in graph 500b lasts a time tₚᵢₓₑₗ, each first pulse 402a in graph 504c lasts a time M*tₚᵢₓₑₗ, and each first pulse 402a in graph 500d lasts a time N*M*tₚᵢₓₑₗ.

The time duration for the second pulses 402b in FIGS. 5B, 5C, and 5D need not coincide with the time duration for the first pulses 402a and is an adjustable (i.e., tunable) time duration in certain embodiments. In this regard, the time duration is related to a size of the second electron beam 214b. For example, in the case of FIGS. 5C and 5F, the time required for each second pulse 402b is less than the time M*tₚᵢₓₑₗ of each pulse 402a in situations in which that second electron beam 214b has a beam diameter that is larger than the beam diameter of the first electron beam 214a.

For example, if the beam diameter of the second electron beam 214b is sufficiently large to cover a full line 504 of pixels 502, the time duration of the second pulse 402b is as short as tₚᵢₓₑₗ in certain embodiments. However, the time duration of the second pulses 402b is determined by the intensity (i.e., electrons per unit time per unit area) of the second electron beam 214b, the diameter of the second electron beam 214b, and the charging state of the sample 202. In this regard, the time duration of each second pulse 402b is variable and need not have the same time duration for each of the second pulses 402b. Similar considerations apply to the time duration of the second pulses 402b for the graph 500d of FIG. 5D. In this regard, the time duration of the second pulses 402b, when treating an entire frame, can be as short as the time N*M*tₚᵢₓₑₗ of the first pulses 402b (depending on the intensity and beam diameter of the second electron beam 214b) and can be longer as needed for charge neutralization of the sample 202. According to various embodiments, each of M and N is an integer between about 200 and about 10,000, however, various other values of M and N are provided in other embodiments.

In certain embodiments, the time duration of the second pulses 402b is a user-selectable second time that is greater than or equal to the one-pixel exposure time and less than or equal to the first time (i.e., the time duration of the first pulse 402a). In other embodiments, the time duration of the second pulses 402b is a variable time duration that is determined automatically by a control system based on an intensity and size of the second electron beam 214b and of a charge state of the sample 202. In this regard, the time duration of the second pulses 402b is determined dynamically and varies from second pulse 402b to second pulse 402b according to various embodiments. Alternatively, the time duration of the second pulses 402b is fixed in certain embodiments and the intensity of the 214b is variable and is dynamically controlled based on a charge state of the sample 202. In still-further embodiments, the time duration and intensity of the second pulses 402b are variable from second pulse 402b to second pulse 402b.

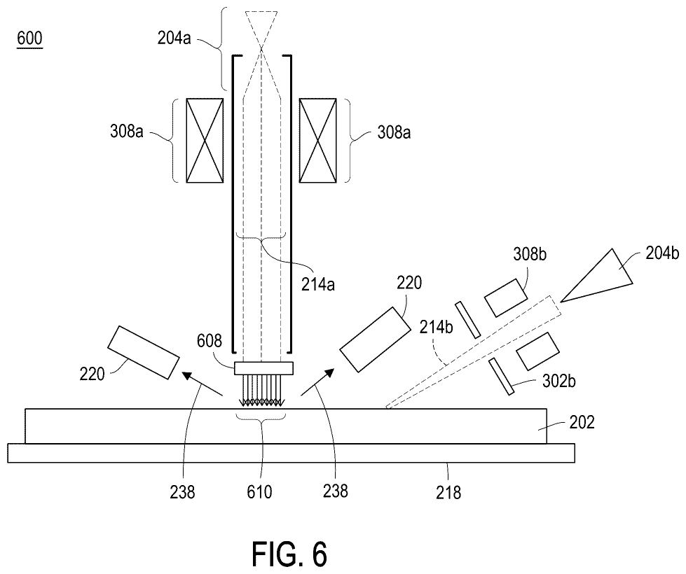

Such treatment by the second electron source 204b not only helps neutralize severe charging immediately following scanning by the first electron beam 214a (i.e., “post-conditioning”), but also can be used to treat the surface to have a positive, negative, or neutral average surface charge state before scanning with the first electron beam 214a (i.e., “pre-conditioning”). Such pre- and post-conditioning with a tunable discharge time (i.e., tunable pulse-timing) is used to generate improved and stable voltage contrast images. According to various embodiments, the second electron source 204b is implemented in a multi-beam electron beam inspection system (see FIG. 6), such that a large spot size of the second electron source 204b (e.g., from about 5 mm to 10 mm) covers a field of view (FOV) (e.g., from about 1 micron to about 500 microns) of the muti-beam electron beam inspection system as described in greater detail with reference to FIG. 6, below.

FIG. 6 is a vertical cross-sectional view of an electron-beam inspection system 600, according to various embodiments. The electron-beam inspection system 600 is configured as an electron multi-beam inspection system. The electron-beam inspection system 600 includes a first electron source 204a configured to generate a first electron beam 214a. The electron-beam inspection system 600 further includes a beam splitter 608 that is configured to generate sub-beams 610 from the first electron beam 214a. As shown, the sub-beams 610 are directed at the sample 202 (such as a wafer having circuit elements formed thereon).

The electron-beam inspection system 600 further includes a first electromagnetic device 308a configured to focus the first electron beam 214a on a beam splitter 608. The sub-beams 610 interact with the sample 202 and generate secondary electrons 238 that are detected by secondary electron detectors 220. According to various embodiments, the sub-beams also produce backscattered electrons 236 (e.g., see FIG. 2) but such backscattered electrons 236 are not explicitly illustrated in this example for simplicity of explanation. As shown in FIG. 6, the electron-beam inspection system 600 further includes a second electron source 204b that generates a second electron beam 214b that acts as a flood gun, as described above with reference to FIGS. 3 to 4D. The second electron beam 214b is shown to have a narrow width for simplicity of illustration but has a wide diameter covering an area larger than the field-of-view of the sub-beams 610.

FIG. 7 is a flowchart of a method 700 of performing an electron beam inspection of a semiconductor substrate 202 according to various embodiments. In operation 702, the method 700 includes generating a first electron beam 214a having a first landing energy LE1 and causing the first electron beam 214a to impinge on a sample 202 at a first angle θ₁. In operation 704, the method 700 includes generating a second electron beam 214b and causing the second electron beam 214b to impinge on the sample 202 at a second angle θ₂ that is different from the first angle θ₁. In operation 706, the method 700 includes detecting electrons emitted by the sample 202 due to interactions with the first electron beam 214a. In operation 708, the method 700 includes controlling a charge state of the sample 202 to be positive, neutral, or negative by varying a second landing energy LE2 of the second electron beam 214b.

According to various embodiments, the method 700 further includes focusing the first electron beam 214a to have a first diameter that is between 1 nm and 50 nm at a surface of the sample 202, scanning the first electron beam 214a over a first area of the sample 202, and providing the second electron beam 214b having a defocused second diameter that is larger than the first diameter such that the second electron beam 214b covers the first area. According to various embodiments, the method 700 further includes generating the first electron beam 214a as a sequence of first pulses 402a, generating the second electron beam 214b as a sequence of second pulses 402b having a time offset relative to the sequence of first pulses 402a such that first pulses 402a and second pulses 402b are alternating (e.g., see FIGS. 5B, 5C, 5D). The method 700 further includes controlling the sequence of first pulses 402a to scan a first area corresponding to a single pixel 502, a line 504 of pixels 502, or a frame 506 of pixels 502, and controlling the sequence of second pulses 402b to impinge on a second area that is greater than the first area and that covers the first area.

Referring to all drawings and according to various embodiments of the present disclosure, a defect detection system (300, 600) is provided. The defect detection system (300, 600) includes a first electron source 204a configured to generate a first electron beam 214a and to cause the first electron beam 214a to impinge on a sample 202, a second electron source 204b configured to generate a second electron beam 214b and to cause the second electron beam 214b to impinge on the sample 202, a detector (220, 222), and a control system (230, 232, 234). The control system (230, 232, 234) is configured to control the first electron source 204a to cause the first electron beam 214a to scan an area of the sample 202 (e.g., see FIGS. 5A to 5G), control a charge state of the sample 202 by varying at least one of a landing energy LE2 and a beam current of the second electron beam 214b, control the detector (220, 222) to detect electrons emitted by the sample 202 due to interactions with the first electron beam 214a, receive a detector signal from the detector (220, 222), and generate a voltage contrast image (e.g., see FIG. 5A) from the detector (220, 222) signal that represents electrons detected by the detector (220, 222).

According to various embodiments, the control system (230, 232, 234) is further configured to control the first electron source 204a such that a first landing energy LE1 of the first electron beam 214a is between about 0.1 keV and about 50 keV, and control the second electron source 204b such that the charge state of the sample 202 is positive, neutral, or negative by varying a second landing energy LE2 of the second electron beam 214b between about 0.1 keV and about 5 keV. According to various embodiments, the control system (230, 232, 234) is further configured to generate the first electron beam 214a as a sequence of first pulses 402a and generate the second electron beam 214b as a sequence of second pulses 402b having a time offset relative to the sequence of first pulses 402a such that first pulses 402a and second pulses 402b are alternating. According to various embodiments, the control system (230, 232, 234) is further configured to control the first electron source 204a such that each one of the sequence of first pulses 402a scans a first area corresponding to a single pixel 502, a line 504 of pixels 502, or a frame 506 of pixels 502, and control the second electron source 204b such that each one of the sequence of second pulses 402b impinges on a second area that is greater than the first area and covers the first area.

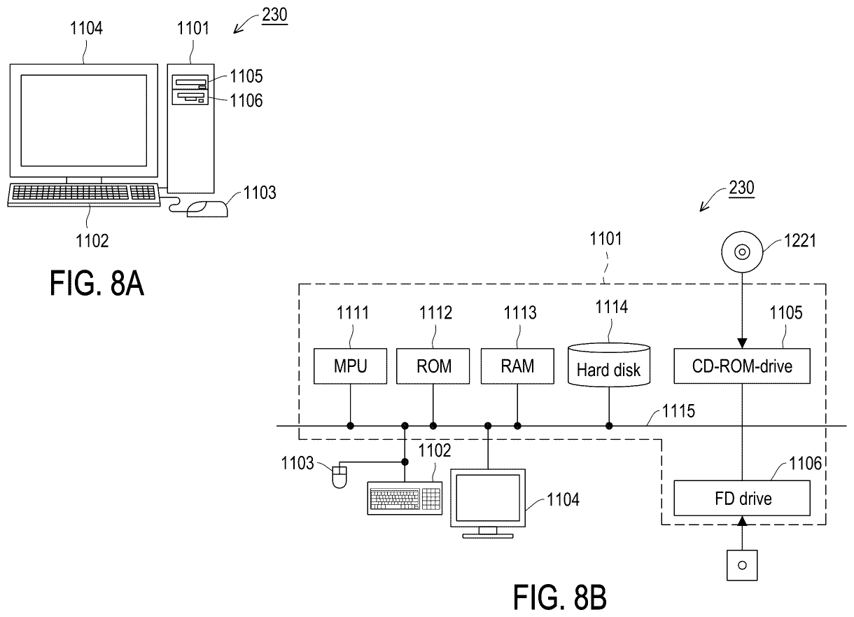

FIGS. 8A and 8B illustrate a computer controller 230 configured to perform the method 700 of FIG. 7, according to various embodiments. FIG. 8A is a schematic view of a computer system that is used to control a defect detection system (300, 600) according to one or more embodiments as described above. All of or a part of the processes, methods, and/or operations of the above-described embodiments can be realized using computer hardware and computer programs executed thereon. In FIG. 8A, a computer system 230 is provided with a computer 1101 including an optical disk read-only memory (e.g., CD-ROM or DVD-ROM) drive 1105 and a magnetic disk drive 1106, a keyboard 1102, a mouse 1103, and a monitor 1104.

FIG. 8B is a diagram showing an internal configuration of the computer system 430. The computer 1101 is provided with, in addition to the optical disk drive 1105 and the magnetic disk drive 1106, one or more processors 1111, such as a micro processing unit (MPU), a read-only memory (ROM) 1112 in which a program, such as a boot-up program is stored, a random access memory (RAM) 1113 that is connected to the MPU 1111 and in which a command of an application program is temporarily stored and a temporary storage area is provided, a hard disk 1114 in which an application program, a system program, and data are stored, and a bus 1115 that connects the MPU 1111, the ROM 1112, and the like. Note that the computer 1101 may include a network card (not shown) for providing a connection to a LAN.

Computer program instructions, configured to cause the computer system 230 to execute the method 700 are stored in a non-transitory computer-readable storage medium, such as an optical disk 1121 or a magnetic disk 1122. Such a storage medium is configured to be inserted into the optical disk drive 1105 or the magnetic disk drive 1106, and transmitted to the hard disk 1114. Alternatively, the program may be transmitted via a network (not shown) to the computer 1101 and stored in the hard disk 1114 (or other non-transitory computer-readable storage medium). At the time of execution, the program is loaded into the RAM 1113. The program may be loaded from the optical disk 1121 or the magnetic disk 1122, or directly from a network. The program does not necessarily need to include, for example, an operating system (OS) or a third-party program to cause the computer 1101 to execute the process for manufacturing a semiconductor device in the foregoing embodiments. The program may only include a command portion to call an appropriate function (module) in a controlled mode and obtain desired results.

Disclosed embodiments are advantageous by providing a second electron source in an electron beam inspection system that generates voltage contrast images. Voltage contrast imaging of electrically floating structures presents at least two challenges. First, the lack of an electron source results in unstable charging on the wafer surface, leading to high nuisance voltage contrast signals. Second, the absence of a grounding path causes severe charging issues due to insufficient neutralizing electrons from the substrate, which can result in image blur, defocus, or electron beam drift during electron beam scanning. These issues—unstable charging and severe charging—can occur independently or simultaneously. Disclosed embodiments address such charging-related challenges related to voltage contrast imaging of electrically isolated structures by providing a second electron source 204b in addition to the primary electron beam 204a used for imaging. The second electron source 204b provides a second electron beam 214b of charge-neutralizing electrons that control the charge state of the floating structure to be positive, neutral, or negative by varying a landing energy landing energy LE and/or an intensity of the second electron beam 214b thus mitigating charging issues and improving the quality of voltage contrast images.

According to various embodiments, a defect detection system includes a first electron source configured to generate a first electron beam and to cause the first electron beam to impinge on a sample at a first angle, and a second electron source configured to generate a second electron beam and to cause the second electron beam to impinge on the sample at a second angle that is different from the first angle, such that a first landing energy of the first electron beam is different from a second landing energy of the second electron beam. According to various embodiments, the first landing energy is between about 0.1 keV and about 50 keV, and the second landing energy is between about 0.1 keV and about 5 keV.

According to various embodiments, the first electron source is located at a first distance from the sample along a first direction that is perpendicular to a surface of the sample, and the second electron source is located at a second distance from the sample along a second direction that subtends an oblique angle relative to the first direction such that the second angle is between about 0° and about 90° relative to the surface of the sample. According to various embodiments, the second electron source is configurable such that the second angle is adjustable.

According to various embodiments, the detection system further includes a stage configured to position the sample relative to the first electron source and the second electron source. In such embodiments, the first electron source is configured to be maintained at a first voltage relative to a voltage of the stage, the second electron source is configured to be maintained at a second voltage relative to the voltage of the stage, and the first voltage is different from the second voltage. According to various embodiments, the system is configured to control a charge state of the sample, which is electrically insulated.

According to various embodiments, the system is configured to provide the first electron beam having a first diameter that is between about 1 nm and about 50 nm at a surface of the sample, and the second electron beam having a second diameter that is between about 6 mm and about 8 mm at the surface of the sample. According to various embodiments, the system is configured to provide the first electron beam having a first electron current that is between about 5.0×10⁻⁹ A and about 1.5×10⁻⁸ A, and the second electron beam having a second electron current that is between about 8.0×10⁻⁵ A and about 1.2×10⁻⁴ A.

According to various embodiments, the first electron source is configured to generate the first electron beam as a sequence of first pulses, and the second electron source is configured to generate the second electron beam as a sequence of second pulses such that each one of the sequence of second pulses includes a time offset relative to the sequence of first pulses such that the sequence of first pulses and the sequence of second pulses are alternating. According to various embodiments, each one of the sequence of first pulses scans a first area corresponding to a single pixel, a line of pixels, or a frame of pixels, and each one of the sequence of second pulses impinges on a second area that is greater than the first area. According to various embodiments, a single pixel area is between about 1 nm and about 50 nm.

According to various embodiments, a one-pixel exposure time is between about 5 ns and about 15 ns, each one of the sequence of first pulses lasts for a first time that is an integer multiple of the one-pixel exposure time depending on whether each one of the sequence of first pulses scans a single pixel, a line of pixels, or a frame of pixels, and each one of the sequence of second pulses lasts for a second time that is greater than or equal to the one-pixel exposure time and less than or equal to the first time.

According to various embodiments, each line includes an integer number M of pixels and each frame includes an integer number N of lines, and each of M and N is an integer between about 200 and about 10,000. According to various embodiments, the detection system further includes a beam splitter that is configured to generate a plurality of sub-beams from the first electron beam such that the plurality of sub-beams span a field-of-view that is less than or equal to 500 microns. According to various embodiments, the second electron beam includes a diameter that is between about 6 mm and about 8 mm at a surface of the sample and that covers the field-of-view of the plurality of sub-beams.

According to various embodiments, a detection system includes a first electron source configured to generate a first electron beam and to cause the first electron beam to impinge on a sample, a second electron source configured to generate a second electron beam and to cause the second electron beam to impinge on the sample, a detector, and a control system. According to various embodiments, the control system is configured to control the first electron source to cause the first electron beam to scan an area of the sample, control a charge state of the sample by varying at least one of a landing energy and a beam current of the second electron beam, control the detector to detect electrons emitted by the sample, receive a detector signal from the detector, and generate a voltage contrast image from the detector signal that represents electrons detected by the detector.

According to various embodiments, the control system is further configured to control the first electron source such that a first landing energy of the first electron beam is between about 0.1 keV and about 50 keV, and control the second electron source such by varying a second landing energy of the second electron beam between about 0.1 keV and about 5 keV. According to various embodiments, the control system is further configured to generate the first electron beam as a sequence of first pulses and generate the second electron beam as a sequence of second pulses including a time offset relative to the sequence of first pulses such that the first pulses and second pulses are alternating.

According to various embodiments, the control system is further configured to control the first electron source such that each one of the sequence of first pulses scans a first area corresponding to a single pixel, a line of pixels, or a frame of pixels, and control the second electron source such that each one of the sequence of second pulses impinges on a second area that is greater than the first area and covers the first area.

According to various embodiments, a method of performing an electron beam inspection of a semiconductor substrate includes generating a first electron beam having a first landing energy and causing the first electron beam to impinge on a sample at a first angle, generating a second electron beam and causing the second electron beam to impinge on the sample at a second angle that is different from the first angle, detecting electrons emitted by the sample, and controlling a charge state of the sample by varying a second landing energy of the second electron beam.

According to various embodiments, the method further includes focusing the first electron beam to have a first diameter that is between about 1 nm and about 50 nm at a surface of the sample, scanning the first electron beam over a first area of the sample, and causing the second electron beam to have a defocused second diameter that is larger than the first diameter and such that the second electron beam covers the first area. According to various embodiments, the method further includes generating the first electron beam as a sequence of first pulses, generating the second electron beam as a sequence of second pulses including a time offset relative to the sequence of first pulses such that first pulses and second pulses are alternating, controlling the sequence of first pulses to scan a first area corresponding to a single pixel, a line of pixels, or a frame of pixels, and controlling the sequence of second pulses to impinge on a second area that is greater than the first area and that covers the first area.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A defect detection system, comprising:
a first electron source configured to generate a first electron beam and to cause the first electron beam to impinge on a sample at a first angle; and
a second electron source configured to generate a second electron beam and to cause the second electron beam to impinge on the sample at a second angle that is different from the first angle,
wherein a first landing energy of the first electron beam is different from a second landing energy of the second electron beam.

2. The defect detection system of claim 1, wherein:
the first landing energy is between 0.1 keV and 50 keV; and
the second landing energy is between 0.1 keV and 5 keV.

3. The defect detection system of claim 1, wherein:
the first electron source is located at a first distance from the sample along a first direction that is perpendicular to a surface of the sample; and
the second electron source is located at a second distance from the sample along a second direction that subtends an oblique angle relative to the first direction such that the second angle is between 0° and 90° relative to the surface of the sample.

4. The defect detection system of claim 3, wherein the second electron source is configurable such that the second angle is adjustable.

5. The defect detection system of claim 1, further comprising:
a stage configured to position the sample relative to the first electron source and the second electron source,
wherein:
the first electron source is configured to be maintained at a first voltage relative to a voltage of the stage;
the second electron source is configured to be maintained at a second voltage relative to the voltage of the stage; and
the first voltage is different from the second voltage.

6. The defect detection system of claim 5, wherein the system is configured to control a charge state of the sample, which is electrically insulated.

7. The defect detection system of claim 1, wherein the system is configured to provide:
the first electron beam having a first diameter that is between 1 nm and 50 nm at a surface of the sample; and
the second electron beam having a second diameter that is between 6 mm and 8 mm at the surface of the sample.

8. The defect detection system of claim 7, wherein the system is configured to provide:
the first electron beam comprising a first electron current that is between 5.0×10⁻⁹ A and 1.5×10⁻⁸ A; and
the second electron beam comprising a second electron current that is between 8.0×10⁻⁵ A to 1.2×10⁻⁴ A.

9. The defect detection system of claim 1, wherein:
the first electron source is configured to generate the first electron beam as a sequence of first pulses; and
the second electron source is configured to generate the second electron beam as a sequence of second pulses such that each one of the sequence of second pulses comprises a time offset relative to the sequence of first pulses such that the sequence of first pulses and the sequence of second pulses are alternating.

10. The defect detection system of claim 9, wherein:
each one of the sequence of first pulses scans a first area corresponding to a single pixel, a line of pixels, or a frame of pixels; and
each one of the sequence of second pulses impinges on a second area that is greater than the first area,
wherein a single pixel area is between 1 nm and 50 nm.

11. The defect detection system of claim 10, wherein:
a one-pixel exposure time is between 5 ns and 15 ns;
each one of the sequence of first pulses lasts for a first time that is an integer multiple of the one-pixel exposure time depending on whether each one of the sequence of first pulses scans a single pixel, a line of pixels, or a frame of pixels; and
each one of the sequence of second pulses lasts for a second time that is greater than or equal to the one-pixel exposure time and less than or equal to the first time.

12. The defect detection system of claim 10, wherein:
each line comprises an integer number M of pixels and each frame comprises an integer number N of lines; and
and each of M and N is an integer between 200 and 10,000.

13. The defect detection system of claim 1, further comprising:
a beam splitter that is configured to generate a plurality of sub-beams from the first electron beam such that the plurality of sub-beams span a field-of-view that is less than or equal to 500 microns,
wherein the second electron beam comprises a diameter that is between 6 mm and 8 mm at a surface of the sample and that covers the field-of-view of the plurality of sub-beams.

14. A defect detection system, comprising:
a first electron source configured to generate a first electron beam and to cause the first electron beam to impinge on a sample;
a second electron source configured to generate a second electron beam and to cause the second electron beam to impinge on the sample;
a detector; and
a control system configured to:
control the first electron source to cause the first electron beam to scan an area of the sample;
control a charge state of the sample by varying at least one of a landing energy and a beam current of the second electron beam;
control the detector to detect electrons emitted by the sample;
receive a detector signal from the detector; and
generate a voltage contrast image from the detector signal that represents electrons detected by the detector.

15. The defect detection system of claim 14, wherein the control system is further configured to:
control the first electron source such that a first landing energy of the first electron beam is between 0.1 keV and 50 keV; and
control the second electron source by varying a second landing energy of the second electron beam between 0.1 keV and 5 keV.

16. The defect detection system of claim 14, wherein the control system is further configured to:
generate the first electron beam as a sequence of first pulses; and
generate the second electron beam as a sequence of second pulses comprising a time offset relative to the sequence of first pulses such that first pulses and second pulses are alternating.

17. The defect detection system of claim 16, wherein the control system is further configured to:
control the first electron source such that each one of the sequence of first pulses scans a first area corresponding to a single pixel, a line of pixels, or a frame of pixels; and
control the second electron source such that each one of the sequence of second pulses impinges on a second area that is greater than the first area and covers the first area.

18. A method of performing an electron beam inspection of a semiconductor substrate, comprising:
generating a first electron beam having a first landing energy and causing the first electron beam to impinge on a sample at a first angle;
generating a second electron beam and causing the second electron beam to impinge on the sample at a second angle that is different from the first angle;
detecting electrons emitted by the sample; and
controlling a charge state of the sample by varying a second landing energy of the second electron beam.

19. The method of claim 18, further comprising:
focusing the first electron beam to have a first diameter that is between 1 nm and 50 nm at a surface of the sample;
scanning the first electron beam over a first area of the sample; and
causing the second electron beam to have a defocused second diameter that is larger than the first diameter and such that the second electron beam covers the first area.

20. The method of claim 18, further comprising:
generating the first electron beam as a sequence of first pulses;
generating the second electron beam as a sequence of second pulses comprising a time offset relative to the sequence of first pulses such that first pulses and second pulses are alternating;
controlling the sequence of first pulses to scan a first area corresponding to a single pixel, a line of pixels, or a frame of pixels; and
controlling the sequence of second pulses to impinge on a second area that is greater than the first area and that covers the first area.
